(19) United States
(12) Patent Application Publication
(10) Pub. No.: US 2012/0049903 A1
(43) Pub. Date: Mar. 1, 2012

(54) LOW NOISE CHARGE PUMP

(75) Inventors: Wonseok Oh, Chandler, AZ (US); Praveen Varma Nadimpalli, Chandler, AZ (US)

(73) Assignee: RF MICRO DEVICES, INC., Greensboro, NC (US)

(21) Appl. No.: 13/045,657

(22) Filed: Mar. 11, 2011

Related U.S. Application Data
(60) Provisional application No. 61/378,237, filed on Aug. 30, 2010.

(51) Int. Cl. H03K 3/01

(52) U.S. Cl. 327/114

(57) ABSTRACT

A delta-sigma modulator is used to generate a dithered clock. The dithered clock is provided as a switching signal to a charge pump to create an output voltage having a reduced noise spectrum. The charge pump may be a regulated charge pump, an unregulated charge pump, a buck charge pump, a boost charge pump, a single phase charge pump, a multi-phase charge pump, or a combination thereof.

### RELATED APPLICATIONS

This application claims the benefit of U.S. provisional patent application No. 61/378,237, filed Aug. 30, 2010, the disclosure of which is incorporated herein by reference in its entirety.

### FIELD OF THE DISCLOSURE

The embodiments disclosed herein are related to charge pump circuits in an integrated circuit. In particular, the embodiments disclosed herein are related to generation of a supply voltage with a charge pump, where the supply voltage has low spectral noise.

### BACKGROUND

There are numerous charge pump designs and schemes. One example a charge pump may include various numbers of switching elements configured to transport charge onto an output capacitor.

Even though there are numerous charge pump designs and schemes, all charge pump schemes include one or more pumping clock signals, which are used to drive switching elements to generate a desired output level. Unfortunately, these pumping clock signals may generate unwanted signal spurs at the output of the charge pump. To minimize the unwanted signal spurs, the charge pump schemes may employ filters and post regulator circuitry. As a result, the power efficiency of these charge pump schemes may be decreased. Accordingly, there is a need to develop a new charge pump architecture that produces a low noise voltage output.

### SUMMARY

Embodiments disclosed in the detailed description relate to uses of a delta-sigma modulation technique to reduce unwanted signal spurs at the output of a charge pump. A delta-sigma modulator may be used to generate a dithered clock. The dithered clock is provided as a switching signal to a charge pump to create an output voltage having a reduced noise spectrum. As a non-limiting exemplary embodiment, the charge pump may be a regulated charge pump, an unregulated charge pump, a buck charge pump, a boost charge pump, a single phase charge pump, a multi-phase charge pump, or some combination thereof.

An exemplary embodiment of a low noise charge pump includes a clock generator coupled to a delta-sigma modulator. The clock generator may be configured to generate a first clock. The delta-sigma modulator may be configured to generate one or more delta-sigma modulated clocks based upon the first clock. A charge pump, in communication with the delta-sigma modulator, may be configured to generate an output voltage based upon the one or more delta-sigma modulated clocks.

Another exemplary embodiment may be a method for generating a low noise supply voltage that may include generating, with a clock generator, a first clock signal. Thereafter, the first clock signal is dithered based upon a random bit sequence to generate a modulated clock signal. An output voltage is generated with a charge pump based upon the modulated clock signal. The random bit sequence may be a pseudo-random bit sequence. The random bit sequence may be generated by a delta-sigma modulator. The delta-sigma modulator may be an n^{th} order delta-sigma modulator.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIGS. 1A-C depict an exemplary embodiment of a charge pump architecture and the corresponding output spectrum.

FIGS. 2A-C depict an exemplary embodiment of a charge pump architecture having a delta-sigma modulated clock and the corresponding output spectrum.

FIG. 3 depicts an exemplary embodiment of a regulated single phase charge pump having pumping clocks generated by delta-sigma modulation of a clock signal.

FIGS. 4A-B depict an output spectrum of a normal clock.

FIGS. 5A-B depict an output spectrum of a delta-sigma modulated clock signal.

FIG. 6 depicts an output spectrum of the exemplary charge pump of FIG. 3, where the normal clock f_{OSC}_{_{—}}_{CLK} of FIGS. 4A-B is used to pump the exemplary charge pump.

FIG. 7 depicts an output spectrum of the exemplary charge pump of FIG. 3, where the delta-sigma modulated clock f_{Δ-Σ}_{_{—}}_{CLK} of FIGS. 5A-B is used to pump the exemplary charge pump.

FIG. 8 depicts a method for generating a low noise supply voltage with a charge pump, and with continuing reference to FIG. 2A.

### DETAILED DESCRIPTION

The exemplary embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

The exemplary embodiments disclosed in the detailed description relate to uses of a delta-sigma modulation technique to reduce unwanted signal spurs at the output of a charge pump. A delta-sigma modulator may be used to generate a dithered clock. The dithered clock is provided as a switching signal to a charge pump to create an output voltage having a reduced noise spectrum. As a non-limiting exemplary embodiment, the charge pump may be a regulated charge pump, an unregulated charge pump, a single phase charge pump, a boost charge pump, a buck-boost charge pump, a buck charge pump, a multi-phase charge pump, or some combination thereof.

As an example, a regulated charge pump regulates the output voltage of the regulated charge pump to deliver a fixed output voltage. As another example, a buck-boost charge pump provides an output voltage that is higher than the input voltage to the boost charge pump. A multi-phase charge pump uses multiple phases of a pumping clock to generate a low ripple output voltage.

An exemplary embodiment of a low noise charge pump includes a clock generator couple to a delta-sigma modulator. The clock generator may be configured to generate a first clock. The delta-sigma modulator may be configured to generate one or more delta-sigma modulated clocks based upon the first clock. A charge pump, in communication with the delta-sigma modulator, may be configured to generate an output voltage based upon the one or more delta-sigma modulated clocks.

An exemplary embodiment may be a method for generating a low noise supply voltage that may include generating, with a clock generator, a first clock signal. Thereafter, the first clock signal is dithered based upon a random bit sequence to generate a modulated clock signal. An output voltage is generated with a charge pump based upon the modulated clock signal. The random bit sequence may be a pseudo-random bit sequence. The random bit sequence may be generated by a delta-sigma modulator. The delta-sigma modulator may be an n^{th} order delta-sigma modulator.

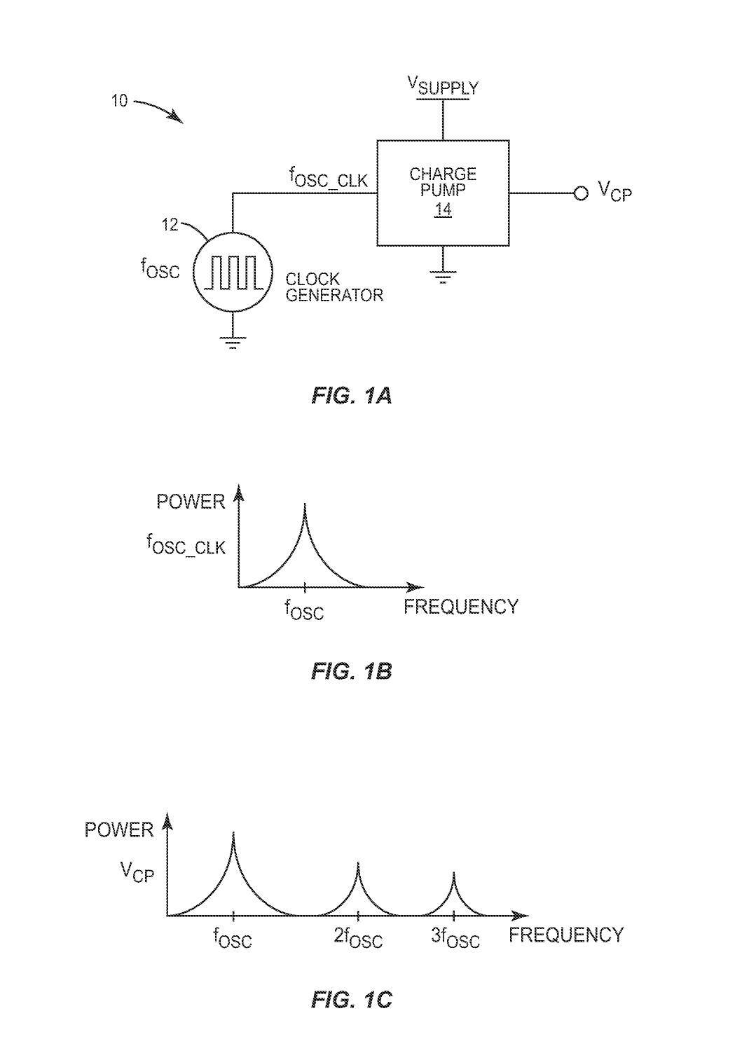

FIG. 1A depicts an exemplary embodiment of a charge pump supply 10 including a clock generator 12 coupled to a charge pump 14. The clock generator 12 may be configured to generate a normal clock f_{OSC}_{_{—}}_{CLK}, which operates at an output frequency f_{OSC}. The charge pump 14 is coupled between a supply voltage V_{SUPPLY} and a reference voltage. The charge pump 14 may be configured to use the normal clock f_{OSC}_{_{—}}_{CLK} as a pumping clock. The charge pump 14 may be a regulated charge pump, an unregulated charge pump, a single-phase charge pump, a bi-phase charge pump, a multiphase charge pump, a booster charge pump, a voltage divider charge pump, or any other type of charge pump. The charge pump 14 generates a charge pump output V_{CP}.

FIG. 1B depicts an exemplary output spectrum of the clock generator 12 of FIG. 1A. As depicted in FIG. 1B, the output spectrum of the clock generator 12, a normal clock f_{OSC}_{_{—}}_{CLK}, has a peak centered at the fundamental oscillating frequency f_{OSC} of the clock generator 12. FIG. 1C depicts an exemplary output spectrum appearing in the charge pump output V_{CP}.

As shown in FIG. 1C, high energy spurs may be generated at the charge pump output V_{CP} by the charge pump 14 at multiples of the fundamental oscillating frequency f_{OSC} of the normal clock f_{OSC}_{_{—}}_{CLK}. The high frequency spurs appearing at the charge pump output V_{CP} degrade the performance of radio frequency (RF) circuits. A non-exhaustive list of exemplary radio frequency circuits may include an RF amplifier, a wideband CDMA RF amplifier, an RF multiplexer, an RF phase lock loop circuit, an RF switch, an RF transceiver, or an RF front end circuit. Although filters and linear regulators may be used to remove the high energy spurs, these additional circuits can degrade power efficiency and increase the cost of the resulting power supply system.

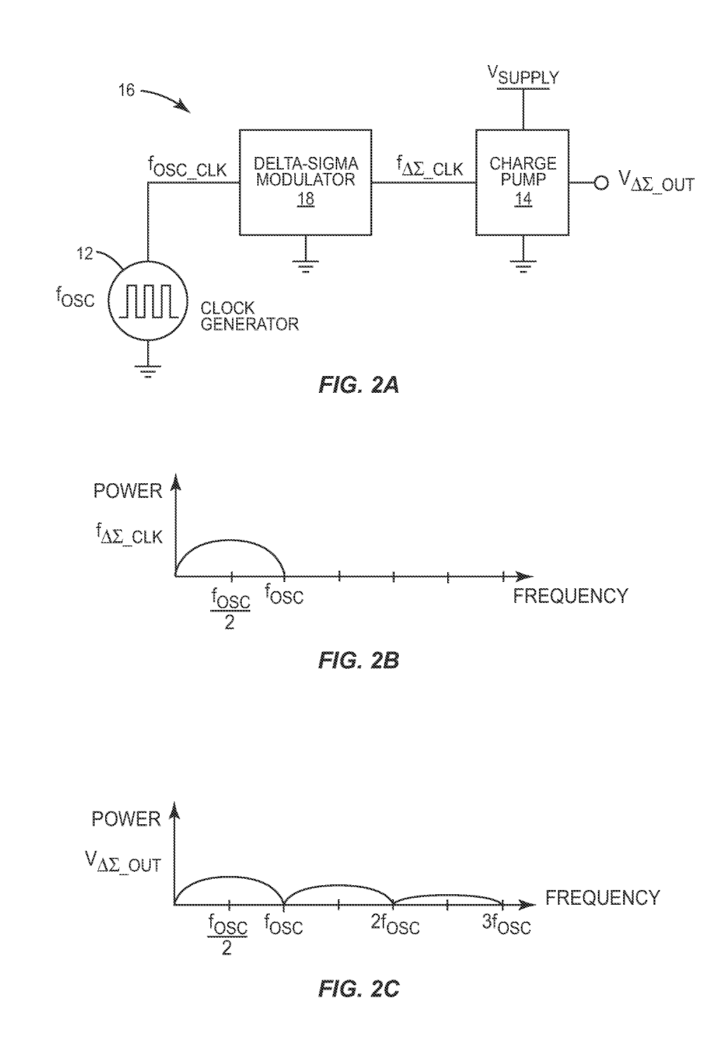

FIG. 2A depicts an exemplary embodiment of a charge pump architecture 16 including a delta-sigma (Δ-Σ) modulator 18. The charge pump architecture 16 of FIG. 2A includes a clock generator 12 configured to provide a normal clock f_{OSC}_{_{—}}_{CLK} to the delta-sigma modulator 18. The delta-sigma modulator may be a first order delta-sigma modulator. Likewise, the delta-sigma modulator may be an n^{th} order delta-sigma modulator. The delta-sigma modulator 18 modulates the normal clock f_{OSC}_{_{—}}_{CLK} to generate a delta-sigma modulated clock f_{Δ-Σ}_{_{—}}_{CLK}. The charge pump 14 may be configured to receive delta-sigma modulated clock f_{Δ-Σ}_{_{—}}_{CLK}. The charge pump 14 may be configured to use the delta-sigma modulated clock f_{Δ-Σ}_{_{—}}_{CLK} as a pumping clock to generate a charge pump output voltage V_{Δ-Σ}_{_{—}}_{OUT} based upon the delta-sigma modulated clock f_{Δ-Σ}_{_{—}}_{CLK}. FIG. 2B depicts the output spectrum of the delta-sigma modulated clock f_{Δ-Σ}_{_{—}}_{CLK} modulated with a first order delta-sigma modulator, which has a peak value centered at f_{OSC}/2. In the case where the delta-sigma modulator 18 is an n^{th} order delta-sigma modulator, the output spectrum of the delta-sigma modulator may be located at f_{OSC}/(2n). As depicted in FIG. 2B, the output spectrum of the delta-sigma modulated clock f_{Δ-Σ}_{_{—}}_{CLK} noticeably lacks the high energy spurs present in the normal clock f_{OSC}_{_{—}}_{CLK} of the clock generator 12. As shown in FIG. 2C, the output spectrum of the charge pump output voltage V_{Δ-Σ}_{_{—}}_{CLK} also lacks the high energy spurs present in the normal clock f_{OSC}_{_{—}}_{CLK}.

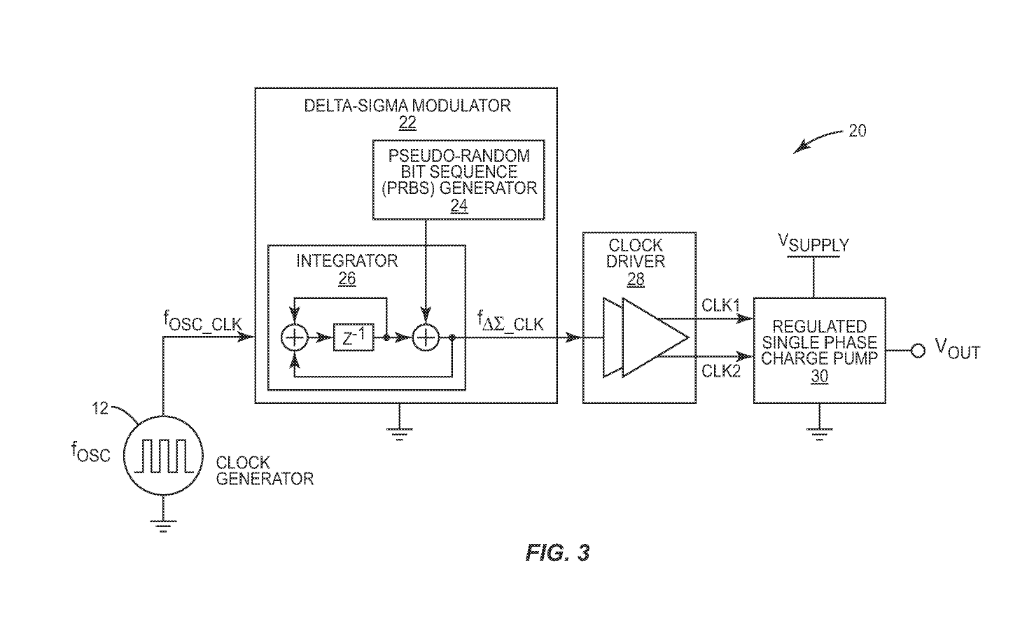

FIG. 3 depicts an exemplary embodiment of a charge pump architecture 20 including a delta-sigma (Δ-Σ) modulator 22 configured to receive the normal clock f_{OSC}_{_{—}}_{CLK} from the clock generator 12. The delta-sigma modulator includes a pseudo-random bit sequence (PRBS) generator 24 coupled to an integrator 26. The delta-sigma modulator 22 generates a delta-sigma modulated clock f_{Δ-Σ}_{_{—CLK}} based upon the pseudo-random bit sequence generated by the pseudo-random bit sequence generator 24.

The charge pump architecture 20 further includes a clock driver 28 and a regulated single phase charge pump 30. Although the charge pump in this exemplary embodiment is a regulated single phase charge pump, the charge pump may be an unregulated charge pump. The clock driver 28 may be configured to receive the delta-sigma modulated clock f_{Δ-Σ}_{_{—}}_{CLK} from the delta-sigma modulator 22. The clock driver 28 may be configured to generate a first pumping clock CLK1 and a second pumping clock CLK2 based upon the delta-sigma modulate clock f_{Δ-Σ}_{_{—}}_{CLK}. The first pumping clock CLK1 and the second pumping clock CLK2 are also delta-sigma modulated clock signals. The regulated single phase charge pump 30 may be configured to receive the first pumping clock CLK1 and the second pumping clock CLK2. The regulated single phase chare pump 30 provides a charge pump output voltage V_{OUT} based upon the first pumping clock CLK1 and the second pumping clock CLK2.

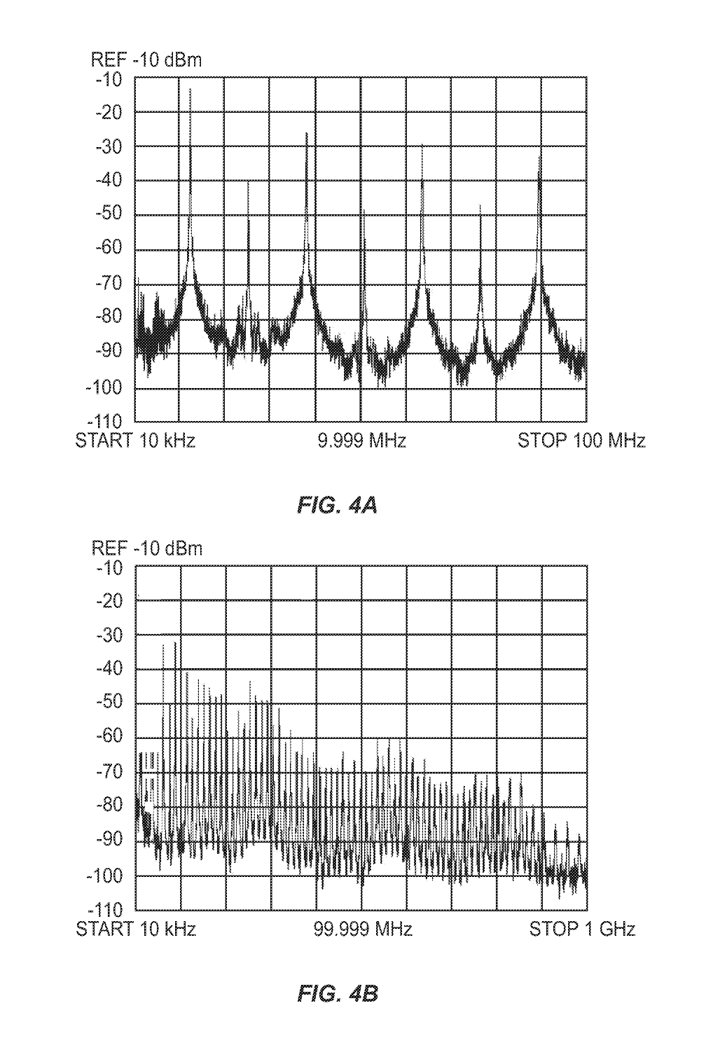

FIG. 4A depicts an output spectrum of the normal clock f_{OSC}_{_{—}}_{CLK} generated by the clock generator 12 of FIG. 3 between 10 Hz and 100 MHz. FIG. 4B depicts an output spectrum of the normal clock f_{OSC}_{_{—}}_{CLK} generated by the clock generator 12 of FIG. 3 between 10 Hz and 1000 MHz.

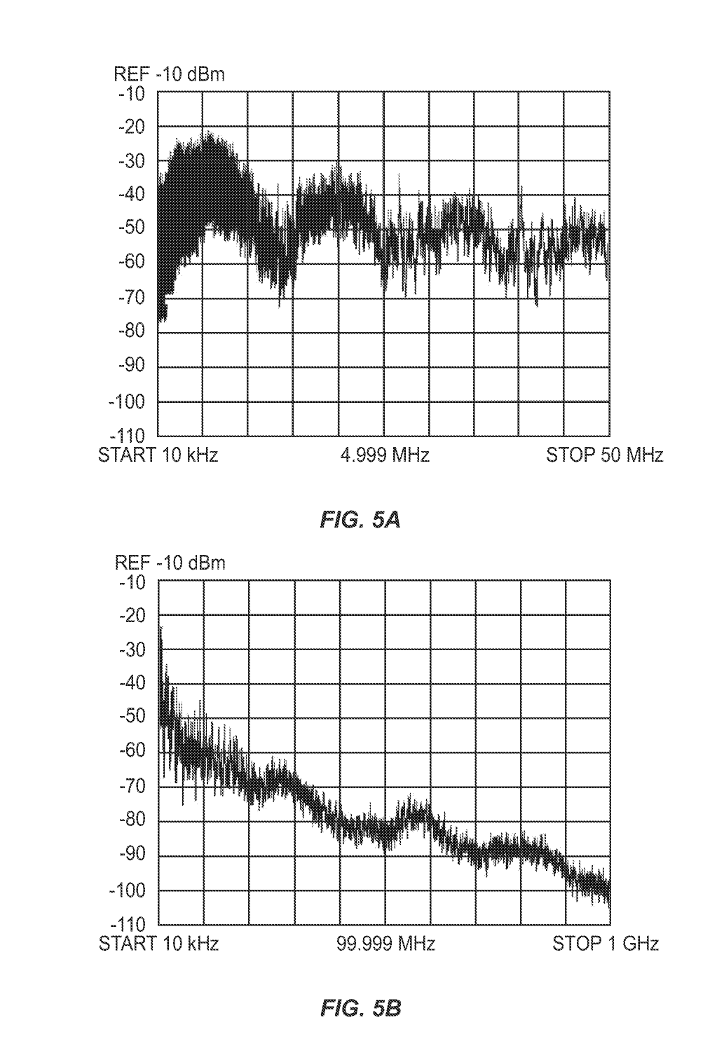

FIG. 5A depicts an output spectrum of the delta-sigma modulated clock f_{Δ-Σ}_{_{—}}_{CLK} generated by the delta-sigma modulator 22 of FIG. 3 between 10 Hz and 100 MHz. FIG. 5B depicts an output spectrum of the delta-sigma modulated clock f_{Δ-Σ}_{_{—}}_{CLK} generated by the delta-sigma modulator 22 of FIG. 3 between 10 Hz and 1000 MHz. As can be adduced by comparison of FIGS. 4A and 4B to FIGS. 5A and 5B, respectively, the output spectrum of the delta-sigma modulated clock f_{Δ-Σ}_{_{—}}_{CLK} is substantially lower than the output spectrum of the normal clock f_{OSC}_{_{—}}_{CLK}.

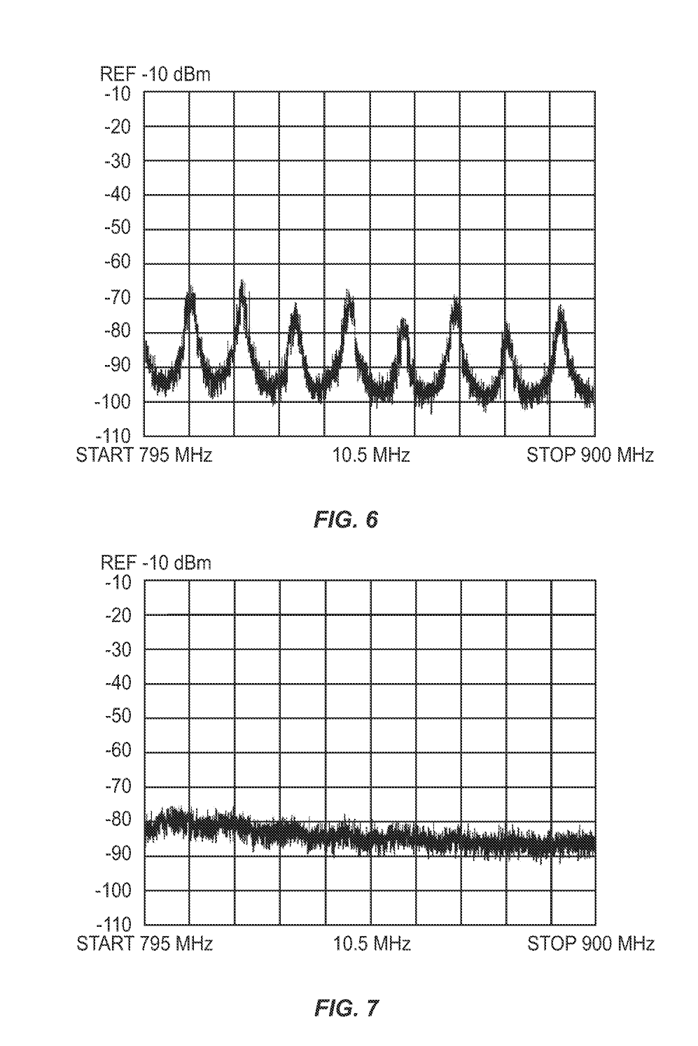

FIG. 6 depicts an output spectrum of the charge pump output voltage generated by the regulated single phase charge pump 30 of FIG. 3 when the delta-sigma modulator 22 is disabled such that the output of the delta-sigma modulator is the normal clock f_{OSC}_{_{—}}_{CLK}.

FIG. 7 depicts an output spectrum of the regulated single phase charge pump 30 of FIG. 3 where the delta-sigma modulated clock f_{Δ-Σ}_{_{—}}_{CLK} of FIGS. 5A-B is used to pump the regulated single phase charge pump 30. As can be adduced by comparison of FIGS. 6 and 7, the output spectrum of the charge pump output voltage V_{ΔA-Σ}_{_{—}}_{OUT} is substantially lower than the output spectrum of the charge pump output voltage when the delta-sigma modulator 22 is disabled.

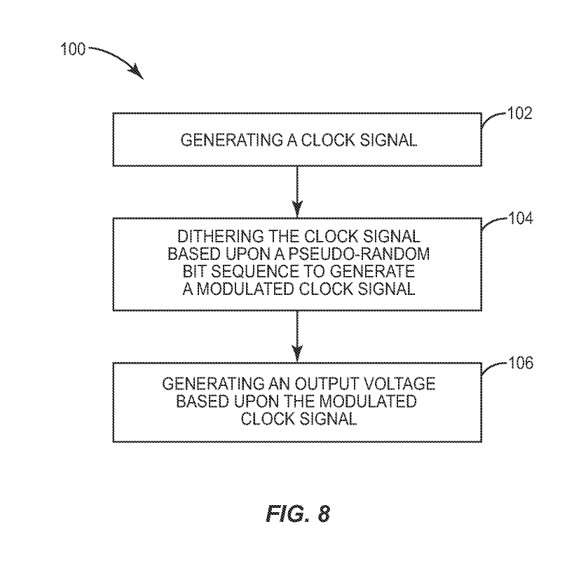

FIG. 8 depicts a method 100 for generating a low noise supply voltage with a charge pump, with continuing reference to FIG. 2A. A first clock f_{OSC}_{_{—}}_{CLK} is generated with a clock generator 12 having a clock frequency f_{OSC}. (Step 102) The first clock f_{OSC}_{_{—}}_{CLK} is dithered to generate a modulated clock signal based upon a pseudo-random bit sequence residing in the delta-sigma modulator 18 or generated by the delta-sigma modulator 18. (Step 104) The modulated clock signal may be a delta-sigma modulated clock signal f_{Δ-Σ}_{_{—}}_{CLK}. The delta-sigma modulator 18 may be an n^{th} order delta-sigma modulator. As an example, the delta-sigma modulated clock signal may be a first order delta-sigma modulated clock or a third order delta-sigma modulated clock. As another example, the modulated clock signal may be based upon a pseudo-random bit sequence. The pseudo-random bit sequence may be stored in a memory of a clock signal modulator (not shown) that is used to modulate the first clock f_{OSC}_{_{—}}_{CLK}. As still another example, the modulated clock signal may be dithered based upon a random number generator. Based upon the delta-sigma modulated clock signal f_{Δ-Σ}_{_{—}}_{CLK}, the charge pump 14 generates a charge pump output voltage V_{Δ-Σ}_{_{—}}_{OUT}. (Step 106)

Those skilled in the art will recognize improvements and modifications to the embodiments of the present disclosure. All such improvements and modifications are considered within the scope of the concepts disclosed herein and the claims that follow.

What is claimed is:

1. A low noise charge pump comprising:
a clock generator configured to generate a first clock;
a delta-sigma modulator coupled to the clock generator, wherein the delta-sigma modulator is configured to generate one or more delta-sigma modulated clocks based upon the first clock; and
a charge pump in communication with the delta-sigma modulator, wherein the charge pump is configured to generate an output voltage based upon the one or more delta-sigma modulated clocks.

2. The low noise charge pump of claim 1 wherein the delta-sigma modulator is a third order delta-sigma modulator.

3. The low noise charge pump of claim 1 wherein the delta-sigma modulator is a first order delta-sigma modulator.

4. The low noise charge pump of claim 1 wherein the charge pump is a single phase charge pump.

5. The low noise charge pump of claim 1 wherein the charge pump is a multi-phase charge pump.

6. The low noise charge pump of claim 1 wherein the delta-sigma modulator includes a pseudo-random bit sequence generator.

7. The low noise charge pump of claim 1 wherein the charge pump is a regulated charge pump.

8. The low noise charge pump of claim 1 wherein the one or more delta-sigma modulated clocks includes a first modulated clock and a second modulated clock, wherein the first modulated clock and the second modulated clock are in phase.

9. A method for generating a low noise supply voltage comprising:
generating, with a clock generator, a first clock signal;
dithering the first clock signal based upon a random bit sequence to generate a modulated clock signal;
generating an output voltage with a charge pump based upon the modulated clock signal.

10. The method of claim 9 wherein dithering the first clock signal based upon the random bit sequence to generate the modulated clock signal comprises generating the modulated clock signal with a delta-sigma modulator.

11. The method of claim 10 wherein the delta-sigma modulator is a third order delta-sigma modulator.

12. The method of claim 10 wherein the delta-sigma modulator is a first order delta-sigma modulator.

13. The method of claim 9 wherein the charge pump is one of a single phase charge pump, a bi-phase charge pump, and a multi-phase charge pump.

14. The method of claim 9 wherein the charge pump is an unregulated charge pump.

15. The method of claim 9 wherein the random bit sequence is a pseudo-random sequence.
